(19) United States
(12) Patent Application Publication
(10) Pub. No.: US 2026/0136451 A1
(43) Pub. Date: May 14, 2026

(54) POWER MODULE AND POWER CONVERSION DEVICE

(71) Applicant: TOYOTA JIDOSHA KABUSHIKI KAISHA, Toyota-shi (JP)

(72) Inventor: Takuya IGUCHI, Tokyo (JP)

(73) Assignee: TOYOTA JIDOSHA KABUSHIKI KAISHA, Toyota-shi (JP)

(21) Appl. No.: 19/348,449

(22) Filed: Oct. 2, 2025

(30) Foreign Application Priority Data
Nov. 11, 2024 (JP) 2024-196678

(51) Int. Cl. H05K 1/02; H05K 1/11; H05K 1/18

(52) U.S. Cl. CPC H05K 1/0203; H05K 1/117; H05K 1/185; H05K 2201/064

(57) ABSTRACT

A power module includes a circuit board including a power semiconductor element, and a cooler including a flow path for a cooling medium that cools the circuit board. The cooler is integrated with the circuit board by being bonded to a surface of the circuit board. A connection terminal capable of being connected to an edge connector is provided at an end portion of the circuit board. An inlet and an outlet of the flow path are opened in a connecting direction of the connection terminal with respect to the edge connector.

### CROSS-REFERENCE TO RELATED APPLICATION

This application is based upon and claims the benefit of priority of the prior Japanese Patent Application No. 2024-196678, filed on November 11, 2024, the entire contents of which are incorporated herein by reference.

### TECHNICAL FIELD

The present disclosure relates to a power module and a power conversion device.

### BACKGROUND

Regarding a power module and a power conversion device, for example, Japanese Unexamined Patent Application Publication No. 2009-296708 describes that, in a power control unit (PCU), power modules each having a transistor mounted thereon are disposed on a base frame and are cooled by a cooler provided below the base frame.

In recent years, a switching element such as a transistor has been made thinner, and a power module has been miniaturized. However, even if the power module is miniaturized, a large high-voltage component (such as a capacitor) is provided in the power conversion device, and is accommodated in the case together with the power modules. Therefore, the space generated by the thinning of the power module cannot be efficiently used, and it is difficult to miniaturize the power conversion device.

### SUMMARY

The present disclosure has been made in view of the above problem, and an object of the present disclosure is to provide a power module and a power conversion device capable of improving space utilization efficiency.

A power module according to the present disclosure includes: a circuit board including a power semiconductor element; and a cooler including a flow path for a cooling medium that cools the circuit board, wherein the cooler is integrated with the circuit board by being bonded to a surface of the circuit board, a connection terminal capable of being connected to an edge connector is provided at an end portion of the circuit board, and an inlet and an outlet of the flow path are opened in a connecting direction of the connection terminal with respect to the edge connector.

In the above power module, the power semiconductor elements may be embedded in the circuit board.

A power conversion device according to the present disclosure includes: the above power modules; a plate member including a plate flow path communicating with the flow path of each of the power modules; the edge connectors arranged on a plate surface of the plate member, the edge connectors being connected to the connection terminals of the circuit boards of the power modules, respectively; the plate surface of the plate member is provided with connection holes that communicate with the plate flow path and are connected to the inlets and the outlets of the flow paths of the power modules; and the power modules are arranged such that surfaces of the circuit boards overlap each other in a direction along the plate surface of the plate member.

Another power conversion device according to the present disclosure includes: the above power modules; a plate member including a plate flow path communicating with the flow path of each of the power modules; an adapter formed into a substantially plate shape, standing in a direction substantially orthogonal to a plate surface of the plate member, and including an adapter flow path connected to the plate flow path, the cooling medium flowing through the adapter flow path; and edge connectors connected to the connection terminals of the circuit board of each of the power modules, respectively, wherein the adaptor is provided with sets of connection holes in a plate surface, the connection holes communicating with the adapter flow path and respectively connected to the inlets and the outlets of the flow paths of the power modules, the edge connectors are arranged, on the plate surface of the adapter, alternately with the sets of connection holes in a direction substantially orthogonal to the plate surface of the plate member, and the power modules are arranged such that the surfaces of the circuit boards overlap each other in the direction substantially orthogonal to the plate surface of the plate member.

In the above power conversion device, the edge connector may include a fixing portion that fixes the power module to the edge connector.

### BRIEF DESCRIPTION OF THE DRAWINGS

FIG. 1A is a plan view illustrating a front surface of a power module according to an embodiment, FIG. 1B is a plan view illustrating a side surface of the power module according to the embodiment, FIG. 1C is a plan view illustrating a rear surface of the power module according to the embodiment, FIG. 1D is a plan view illustrating a lower surface of the power module according to the embodiment, and FIGS. 1E and 1F are cross-sectional views illustrating an example of an internal structure of a cooler;

FIG. 2A is a plan view illustrating a connection structure of a connection destination of the power module in a top view, and FIGS. 2B and 2C are plan views illustrating an example of a state in which the power module and the connection structure are connected to each other;

FIG. 3A is a plan view illustrating front surfaces of a power module and an edge connector according to another embodiment, FIG. 3B is a plan view illustrating upper surfaces of the power module and the edge connector according to the other embodiment, FIG. 3C is a plan view illustrating front surfaces of a power module and an edge connector according to yet another embodiment, and FIG. 3D is a plan view illustrating upper surfaces of the power module and the edge connector according to the yet other embodiment;

FIG. 4A is a top view illustrating an example of a PCU, and FIG. 4B is a side view illustrating an example of the PCU;

FIG. 5A is a top view illustrating an example of another PCU, FIG. 5B is a side view illustrating an example of the other PCU, and FIG. 5C is a cross-sectional view taken along line D-D of FIG. 5A; and

FIG. 6A is a plan view illustrating an example of an adapter in a front view, and FIG. 6B is a cross-sectional view taken along line E-E of FIG. 6A.

### DETAILED DESCRIPTION

### [Power Module]

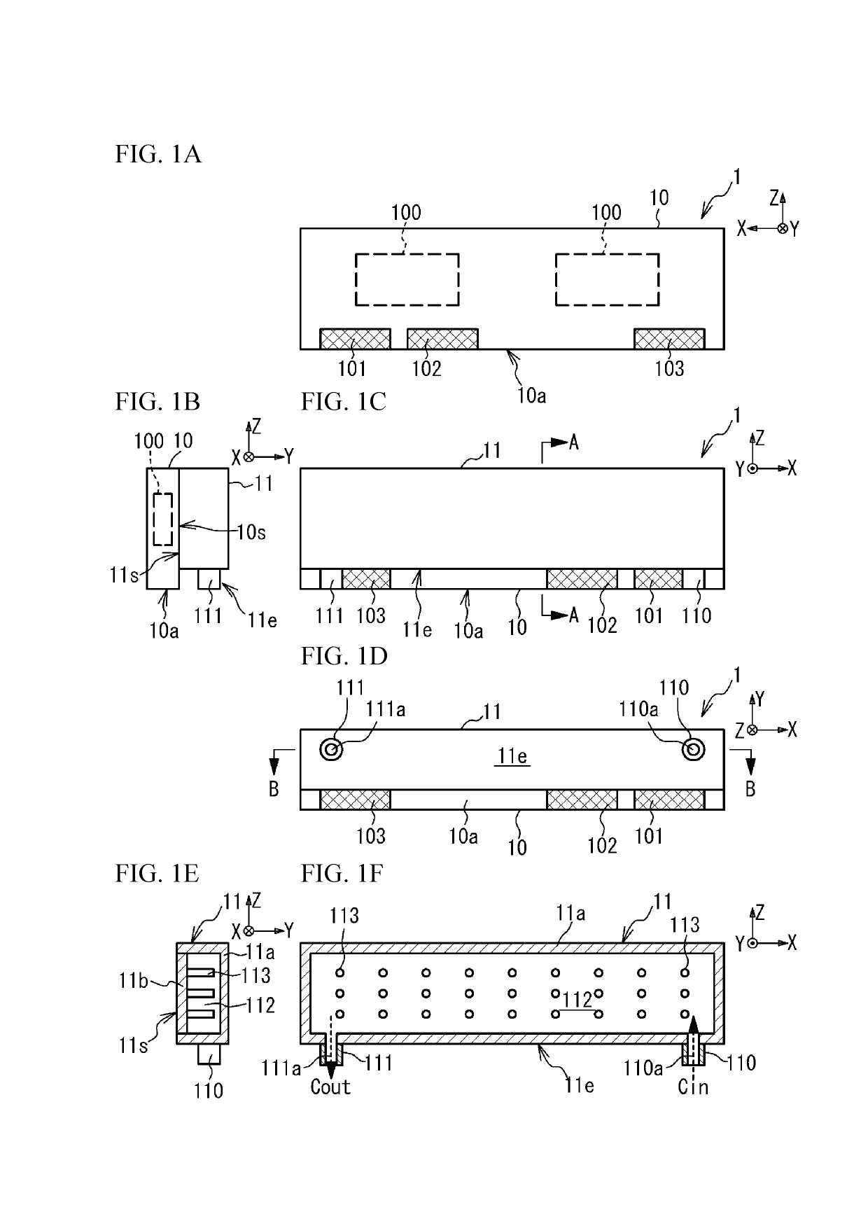

FIG. 1A is a plan view illustrating a front surface of a power module 1 according to an embodiment. FIG. 1B is a plan view illustrating a side surface of the power module 1 according to the embodiment. FIG. 1C is a plan view illustrating a rear surface of the power module 1 according to the embodiment. FIG. 1D is a plan view illustrating a lower surface of the power module 1 according to the embodiment. The power module 1 includes a circuit board 10 and a cooler 11 which are integrated with each other. The circuit board 10 is provided on the front side of the power module 1, and the cooler 11 is provided on the rear side of the power module 1. In FIGS. 1A to 1D, an X direction, a Y direction, and a Z direction orthogonal to one another are illustrated. In the other drawings, the X direction, the Y direction, and the Z direction are similarly illustrated.

The circuit board 10 has, for example, a rectangular shape. For example, two intelligent power modules (IPMs) 100 are mounted on the circuit board 10 as an example of power semiconductor elements. The IPMs 100 are embedded in the circuit board 10. The IPM 100 includes a switching element such as an insulated gate bipolar transistor (IGBTs), a freewheeling diode connected in parallel to the switching element, and the like, and these are incorporated in the circuit board 10. Therefore, the power module 1 is made thinner than in the case where the IPM 100 is a surface-mounted chip. The IPM 100 may be formed as a surface-mounted chip.

Connection terminals 101 to 103 to be connected to an edge connector described later are provided on an end portion 10a in the Z direction which is one side in the longitudinal direction (X direction) of the circuit board 10. For example, the connection terminal 101 is a positive input terminal, the connection terminal 102 is a negative input terminal, and the connection terminal 103 is an output terminal.

The cooler 11 has a substantially rectangular parallelepiped shape. The cooler 11 cools the circuit board 10. The cooler 11 includes a joint surface 11s joined to a plate surface 10s of the circuit board 10. The plate surface 10s of the circuit board 10 and the joint surface 11s of the cooler 11 are joined to each other in a state of facing each other in the Y direction. In this case, the joining means may be, for example, an adhesive or a fastening mechanism such as a bolt, but is not limited thereto.

The cooler 11 is bonded to the plate surface 10s of the circuit board 10, and is thereby integrated with the circuit board 10. Therefore, the circuit board 10 radiates heat from the plate surface 10s. Note that, of the plate surface 10s, the end portion 10a provided with the connection terminals 101 to 103 is not joined to the joint surface 11s, and is exposed so as to be connectable to the edge connector. The plate surface 10s of the circuit board 10 is an example of a surface of the circuit board 10.

An inflow portion 110 and an outflow portion 111 for cooling water for cooling the circuit board 10 are provided at a side surface 11e of the cooler 11 on the end portion 10a of the circuit board 10. The inflow portion 110 and the outflow portion 111 each have a cylindrical shape and protrude from the side surface 11e in the negative Z direction. The inflow portion 110 has an inlet 110a through which the cooling water flows in, and the outflow portion 111 has an outlet 111a through which the cooling water flows out. The inlet 110a and the outlet 111a have a circular shape as an example, but are not limited to this shape.

FIGS. 1E and 1F are cross-sectional views illustrating an example of the internal configuration of the cooler 11. FIG. 1E illustrates a cross section taken along line A-A of FIG. 1C, and FIG. 1F illustrates a cross section taken along line B-B of FIG. 1D. A flow path 112 through which the cooling water flows is provided inside the cooler 11. The flow path 112 communicates with the inlet 110a and the outlet 111a.

The cooler 11 has a cover portion 11a and a base portion 11b connected to each other. The base portion 11b is made of a highly heat-conductive material and has a rectangular plate shape. The cover portion 11a has a box shape in which a surface of a hollow substantially rectangular parallelepiped is opened, and the opened surface is sealed by the base portion 11b, thereby forming the flow path 112 having a substantially rectangular parallelepiped shape inside. The inflow portion 110 and the outflow portion 111 are provided on the side surface 11e of the cover portion 11a. The cooling water enters the flow path 112 from the inlet 110a (see reference sign Cin) and exits to the outside from the outlet 111a (see reference sign Cout). As a means for connecting the cover portion 11a and the base portion 11b, a waterproof adhesive may be used, but the means is not limited thereto.

Cylindrical fins 113 are provided on a plate surface of the base portion 11b so as to be immersed in the flow path 112. The fins 113 stand in a direction substantially perpendicular to the plate surface of the base portion 11b (in the negative X direction). The joint surface 11s is opposite to the fins 113. Heat generated from the circuit board 10 is transferred to the fins 113 from the joint surface 11s, and the circuit board 10 is cooled by the cooling water. As described above, since the cooler 11 includes the fins 113, the heat dissipation area is increased as compared with the case where the fins 113 are not provided. The cooling water is an example of a cooling medium.

The inlet 110a and the outlet 111a of the flow path 112 are opened in the connecting direction (the negative Z direction) of the connection terminals 101 to 103 with respect to the edge connector. Therefore, by providing an opening of a passage for cooling water adjacent to the edge connector of the connection destination, the power module 1 is connected in an arbitrary direction. The connection structure of the connection destination of the power module 1 will be described below.

### (Connection Structure)

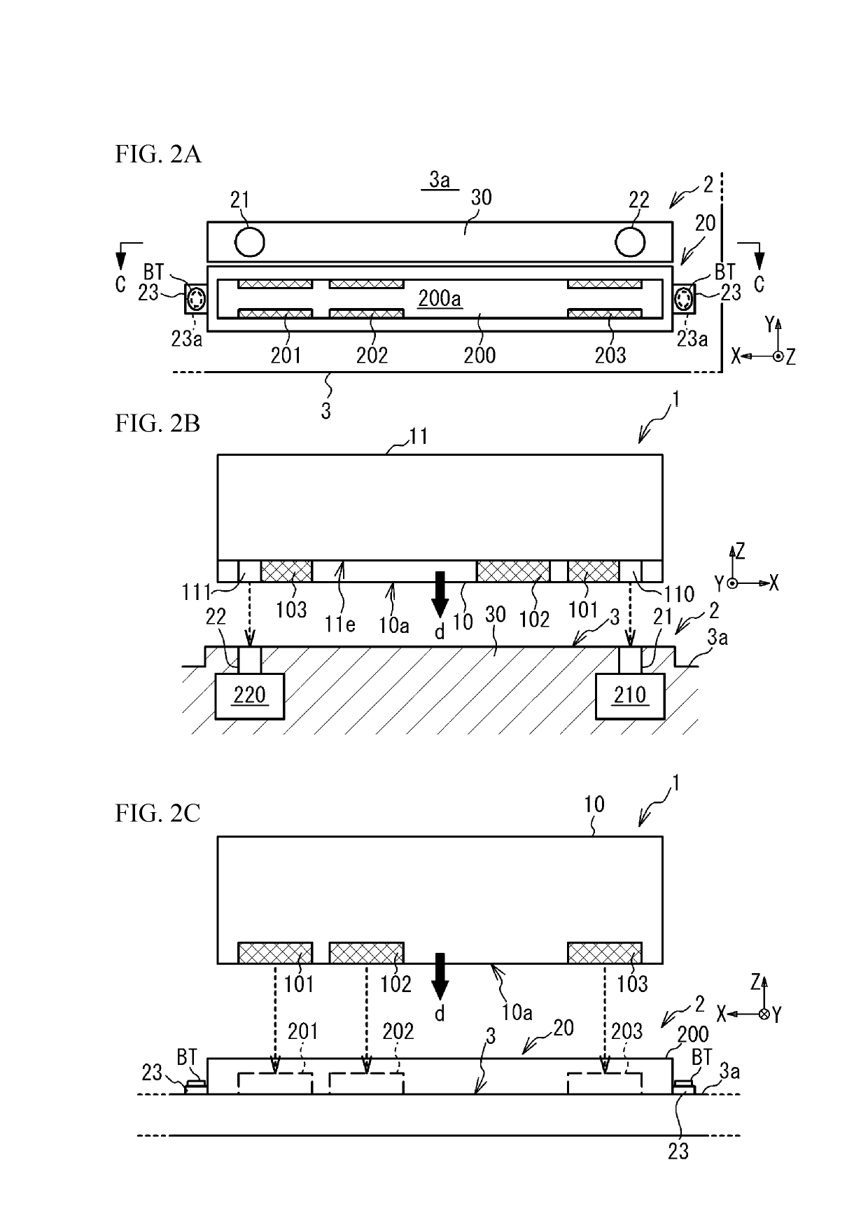

FIG. 2A is a plan view illustrating the connection structure 2 of the connection destination of the power module 1 in a top view. FIGS. 2B and 2C are plan views illustrating an example of a state in which the power module 1 and the connection structure 2 are connected to each other. Here, FIG. 2B illustrates a cross section of the base plate 3 taken along line C-C of FIG. 2A and the cooler 11 in a front view along the Y direction. FIG. 2C illustrates the circuit board 10 and an edge connector 20 in a front view along the Y direction. In FIGS. 2A and 2B, the same reference numerals are given to the same components as those in FIGS. 1A to 1F, and the description thereof will be omitted.

The connection structure 2 is provided on, for example, a base plate 3 of a PCU, and includes the edge connector 20 and connection holes 21 and 22. The base plate 3 is a bottom plate of the PCU and is made of, for example, a metal having high rigidity. A pedestal portion 30 protruding from a plate surface 3a in the positive Z direction is provided on the plate surface 3a of the base plate 3. The pedestal portion 30 supports the cooler 11 in the Z direction. The base plate 3 is an example of a plate member.

The edge connector 20 is made of, for example, resin. The edge connector 20 includes a main body portion 200 and a pair of plate portions 23. The main body portion 200 has a box shape in which a surface of a substantially rectangular parallelepiped is opened. The main body portion 200 has a slot 200a that is open in the Z direction and extends in the X direction. The end portion 10a of the circuit board 10 is inserted into the slot 200a. Connector terminals 201 to 203 connected to the connection terminals 101 to 103 of the circuit board 10, respectively, are provided on inner walls of a slot 20a. The connector terminals 201 to 203 are formed as a pair of plate springs so as to fix the connection terminals 101 to 103 in a sandwiched state.

The pair of plate portions 23 are provided at both ends of the main body portion 200 in the longitudinal direction (X direction). The plate portion 23 is located at the lowermost portion of the edge connector 20 in the Z direction so as to be in contact with the plate surface 3a of the base plate 3. The plate portion 23 is formed with an insertion hole 23a for inserting a bolt BT therethrough, and the edge connector 20 is fixed to the base plate 3 by the bolt BT inserted through the plate portion 23. Note that the illustration of holes for the bolt BT on the base plate 3 is omitted.

The connection holes 21 and 22 each have a circular shape, and are provided in the pedestal portion 30 of the base plate 3 so as to be adjacent to the edge connector 20 in the Y direction. The dimensions of the pedestal portion 30 in the Z direction are substantially equal to the distances from the side surface 11e of the cooler 11 to the end portion 10a of the circuit board 10. The connection holes 21 and 22 are arranged in the X direction in the vicinity of both end portions of the main body portion 200 in the X direction. The connection holes 21 and 22 communicate with plate flow paths 210 and 220 provided inside the base plate 3, respectively. The cooling water flows between the plate flow paths 210 and 220 and a cooling system (not illustrated) including an external pump.

The inflow portion 110 and the outflow portion 111 of the cooler 11 are inserted into the connection holes 21 and 22 and, respectively (see the dotted arrows). Here, a sealing structure such as ring-shaped rubber members is provided between the inflow portion 110 and the outflow portion 111 and the connection holes 21 and 22 respectively so as not to leak the cooling water. The inflow portion 110 and the outflow portion 111 are inserted into the connection holes 21 and 22, respectively. Thus, the inlet 110a of the flow path 112 of the cooler 11 is connected to the connection hole 21, and the outlet 111a of the flow path 112 of the cooler 11 is connected to the connection hole 22.

Thus, the flow path 112 of the cooler 11 and the plate flow paths 210 and 220 of the base plate 3 communicate with each other. The cooling water flows into the flow path 112 of the cooler 11 from the plate flow path 210 to cool the circuit board 10, and is discharged from the flow path 112 to the plate flow path 220. The plate flow paths 210 and 220 each extends along the Y direction inside the base plate 3.

The power module 1 is connected by moving in the connecting direction d with respect to the connection structure 2. The connecting direction d is a direction substantially perpendicular to the plate surface 3a of the base plate 3. When the power module 1 is connected, the connection terminals 101 to 103 of the circuit board 10 are connected to the connector terminals 201 to 203 of the edge connector 20, respectively, and the inlet 110a and the outlet 111a of the flow path 112 of the cooler 11 are connected to the connection holes 21 and 22 and of the base plate 3, respectively.

As described above, the power module 1 has a configuration in which the coolers 11 and the circuit boards 10 having the same connection direction d with respect to the connection structure 2 are integrated by joining the joint surface 11s and the plate surface 10s. Therefore, when the power module 1 is mounted on a device such as a PCU, the power module 1 is capable of being connected to the base plate 3 of the device in any direction while having a capability of sufficiently cooling the IPM 100 that generates a large amount of heat. Therefore, according to the power module 1, the use efficiency of the space in the device is improved. The posture of each power module 1 is not limited to the posture in which the plate surface 10s of the circuit board 10 is orthogonal to the plate surface 3a of the base plate 3 as in the present example. The plate surface 10s of the circuit board 10 may be inclined at a certain angle with respect to the plate surface 3a of the base plate 3.

### (Other Embodiments)

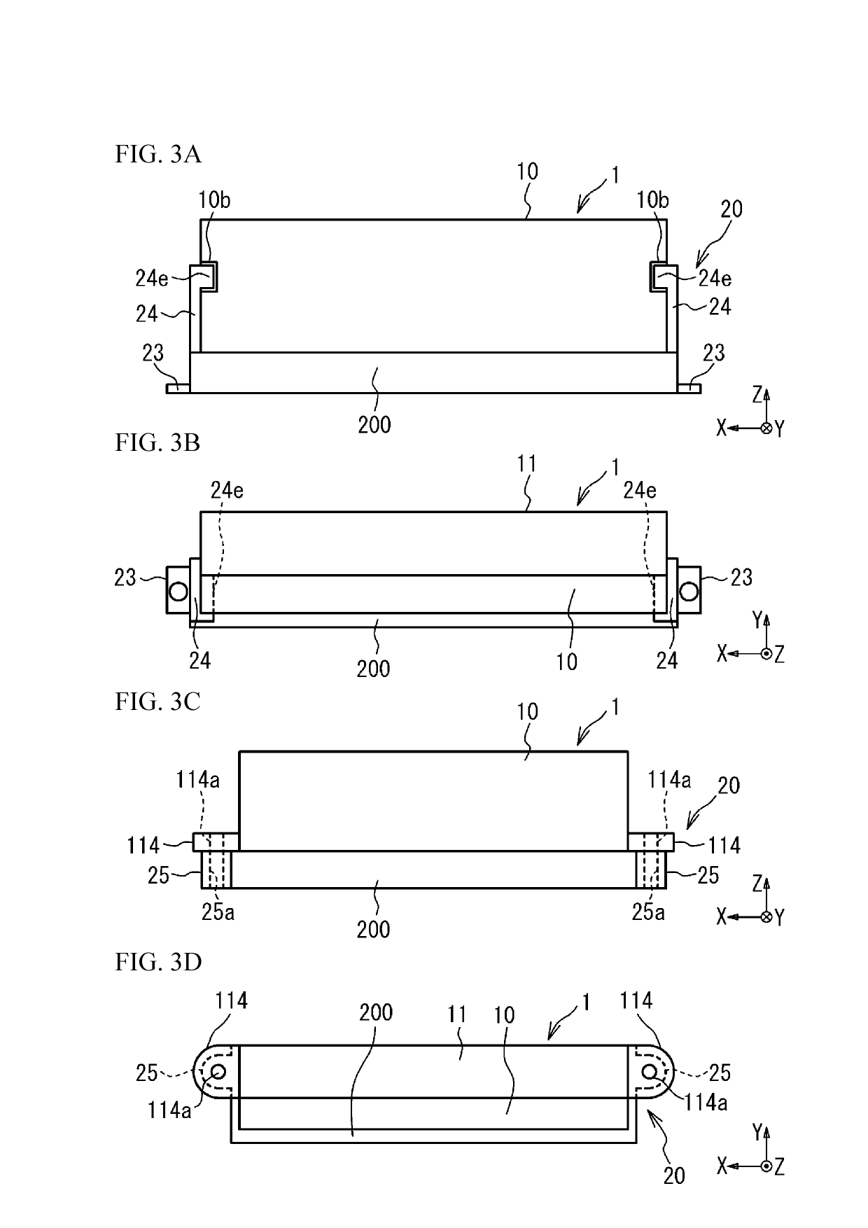

FIG. 3A is a plan view illustrating the front surfaces of the power module 1 and the edge connector 20 according to another embodiment. FIG. 3B is a plan view illustrating the upper surfaces of the power module 1 and the edge connector 20 according to the other embodiment. FIGS. 3A and 3B illustrate a state in which the circuit board 10 is inserted into the edge connector 20. In FIGS. 3A and 3B, the same reference numerals are given to the same components as those in FIGS. 1A to 1F and FIGS. 2A to 2C, and the description thereof will be omitted.

The edge connector 20 has a pair of claw portions 24 for fixing the circuit board 10. The claw portions 24 have elasticity and extend in the connecting direction (Z direction) of the circuit board 10 from both end portions of the main body portion 200 in the longitudinal direction (X direction), respectively. Tips 24e of the claw portions 24 are bent in the X direction and are engaged with cutout portions 10b formed at both ends of the circuit board 10 in the X direction, respectively.

Thus, the circuit board 10 is fixed to the edge connector 20. The claw portion 24 is an example of a fixing portion that fixes the power module 1 to the edge connector 20.

FIG. 3C is a plan view illustrating the front surfaces of the power module 1 and the edge connector 20 according to yet another embodiment. FIG. 3D is a plan view illustrating the upper surfaces of the power module 1 and the edge connector 20 according to the yet other embodiment. FIGS. 3C and 3D illustrate a state in which the circuit board 10 is inserted into the edge connector 20. In FIGS. 3C and 3D, the same reference numerals are given to the same components as those in FIGS. 1A to 1F and FIGS. 2A to 2C, and the description thereof will be omitted.

The edge connector 20 is provided with a pair of fixing portions 25 each having a substantially columnar shape for fixing the cooler 11. The fixing portions 25 are adjacent to both end portions of the main body portion 200 in the longitudinal direction (X direction), respectively. The fixing portions 25 are adjacent to the both ends in the positive Y direction thereof. The cooler 11 is provided with a pair of plate-like projecting portions 114 projecting outward from both ends thereof in the X direction so as to overlap the fixing portions 25 in the Z direction, respectively.

The fixing portion 25 and the projecting portion 114 are provided with fastening holes 25a and 114a for inserting bolts (not illustrated), respectively. When the circuit board 10 is inserted into the edge connector 20, the fastening holes 25a and 114a overlap each other. The cooler 11 are fixed to the edge connector 20 by fastening bolts to the fastening holes 25a and 114a.

When the power module 1 is fixed to the edge connector 20 in this manner, the power module 1 is prevented from being detached from the edge connector 20 due to external force such as vibration.

### (Configuration of PCU)

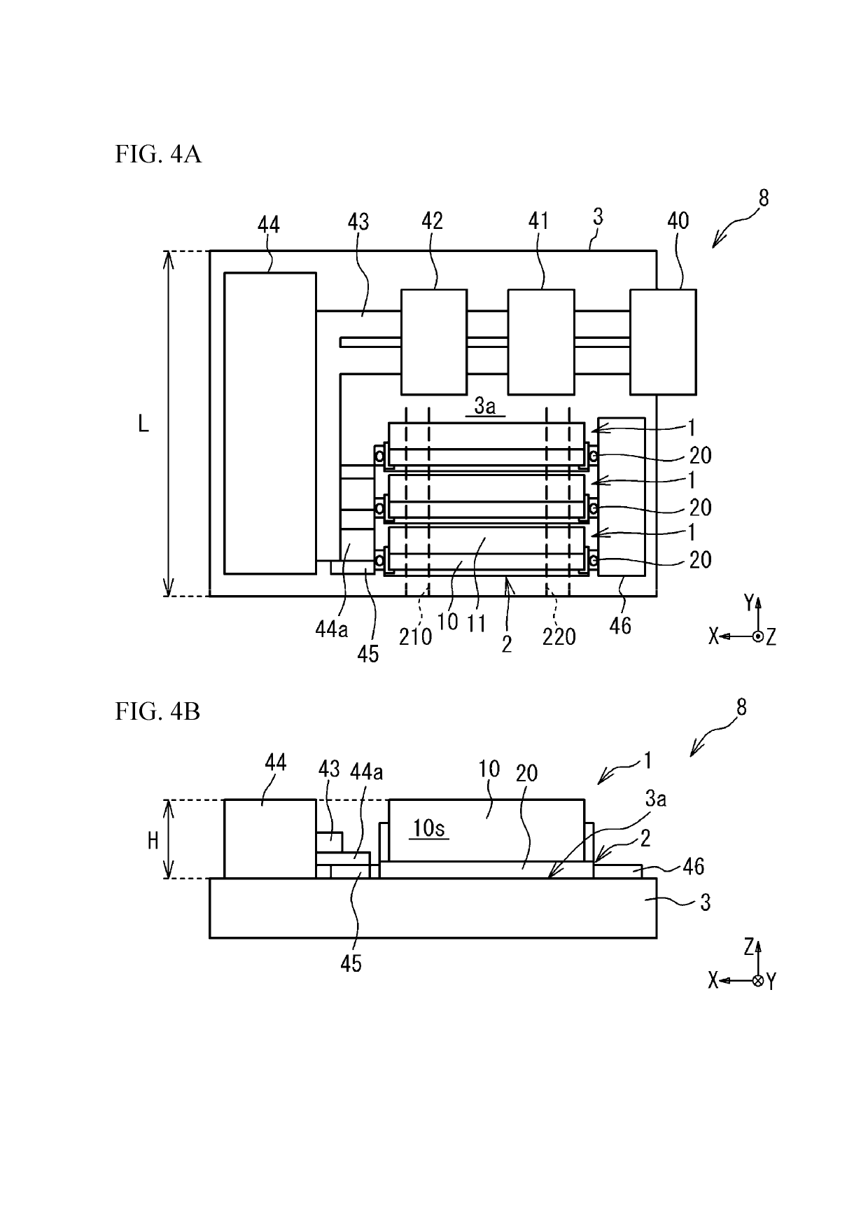

FIG. 4A is a top view illustrating an example of a PCU 8. FIG. 4B is a side view illustrating an example of the PCU 8. In FIGS. 4A and 4B, the same reference numerals are given to the same components as those in FIGS. 1A to 2C, and the description thereof will be omitted.

The PCU 8 is an example of a power conversion device. The PCU 8 includes the base plate 3, three sets of the power modules 1 and the edge connectors 20, an external connector 40, an electromagnetic compatibility (EMC) filters 41 and 42, a wiring 43, a capacitor 44, and terminal blocks 45 and 46. The three sets of the power modules 1 and the edge connectors 20, the external connector 40, the EMC filters 41 and 42, the wiring 43, the capacitor 44, and the terminal blocks 45 and 46 are mounted on the plate surface 3a of the base plate 3. The plate flow paths 210 and 220 extending in the Y direction are provided inside the base plate 3 so as to overlap the edge connectors 20 in a front view.

The two IPMs 100 are mounted on the circuit board 10 of each power module 1 to constitute inverters. One of the two IPM 100 switches functions as an upper arm of the invertor, and the other switch functions as a lower arm of the invertor. Thus, the circuit board 10 of each power module 1 converts a direct current input from the connector terminals 201 and 202 of each edge connector 20 into an alternating current and outputs the alternating current to the connector terminal 203 of each edge connector 20. The number of the IPMs 100 mounted on the circuit board 10 is not limited.

The capacitor 44 is, for example, a film capacitor, and is connected in parallel to switch elements of the two IPMs 100 to smooth the voltage. The pair of terminals 44a of the capacitor 44 are electrically connected to lead terminals (not illustrated) led out from the connector terminals 201 and 202 of each edge connector 20.

The EMC filters 41 and 42 are electrically connected to the external connector 40 and the terminals 44a of the capacitor 44 via the wiring 43, and reduces electromagnetic radiation generated by energization. The external connector 40 is electrically connected to, for example, a lithium ion battery via a cable (not illustrated).

The other terminal block 46 is provided with a lead terminal (not illustrated) led out from the connector terminal 203 of each edge connector 20. Each of the lead terminals of the terminal block 46 is electrically connected to, for example, a three phase AC motor (not illustrated).

The base plate 3 is provided with three connection structures 2 corresponding to the three power modules 1, respectively. The three edge connectors 20 are arranged in the Y direction between the terminal blocks 45 and 46 on the plate surface 3a of the base plate 3. Here, the longitudinal direction of each edge connector 20 substantially coincides with the X direction. The circuit board 10 is inserted into each edge connector 20 in a posture substantially perpendicular to the plate surface 3a of the base plate 3 (Z direction). Further, the inlet and the outlet of the flow path 112 of the cooler 11 of each power module 1 are connected to the connection holes 21 and 22 provided in the plate surface 3a of the base plate 3, respectively, as described with reference to FIG. 2B. The edge connectors 20 and the connection holes 21 and 22 are alternately arranged in the Y direction. In FIGS. 4A and 4B, the pedestal portion 30 and the connection holes 21 and 22 are not illustrated.

With the above configuration, the power modules 1 are arranged such that the plate surfaces 10s of the circuit boards 10 overlap one another in the Y direction along the plate surface 3a of the base plate 3. According to this arrangement, the dimension in the Y direction, which is the thickness direction of the circuit board 10, is the smallest among the dimensions of the power module 1 in the X direction, the Y direction, and the Z direction. Therefore, the dimension L of the base plate 3 in the Y direction is reduced. In contrast, if the power modules 1 are arranged in the Y direction on the plate surface 3a of the base plate 3 such that the plate surface 10s of the circuit board 10 is parallel to the plate surface 3a of the base plate 3, the size L of the base plate 3 in the Y direction is increased as compared with the present example.

In the Z direction, the height of the PCU 8 is most affected by the size H of the capacitor 44, which is a large component among the electrical components mounted on the base plate 3. Therefore, as described above, if the power modules 1 are arranged in the Y direction on the plate surface 3a of the base plate 3 such that the plate surface 10s of the circuit board 10 is parallel to the plate surface 3a of the base plate 3, a useless space is generated above the power modules 1 in the Z direction (in the positive Z direction).

However, as in the present example, when the power modules 1 are arranged such that the plate surfaces 10s of the circuit boards 10 are overlapped in the Y direction along the plate surface 3a of the base plate 3, the circuit boards 10 are held in a posture of standing up with respect to the plate surface 3a of the base plate 3. Therefore, unlike the above case, it is possible to effectively utilize the space of the PCU 8 by eliminating a wasteful space, and it is possible to reduce the size of the PCU 8.

The power module 1 in the PCU 8 is not limited to the above-described mounting form. The three power modules 1 may be mounted on the plate surface 3a of the base plate 3 so as to overlap in the Z direction. Other mounting modes will be described below.

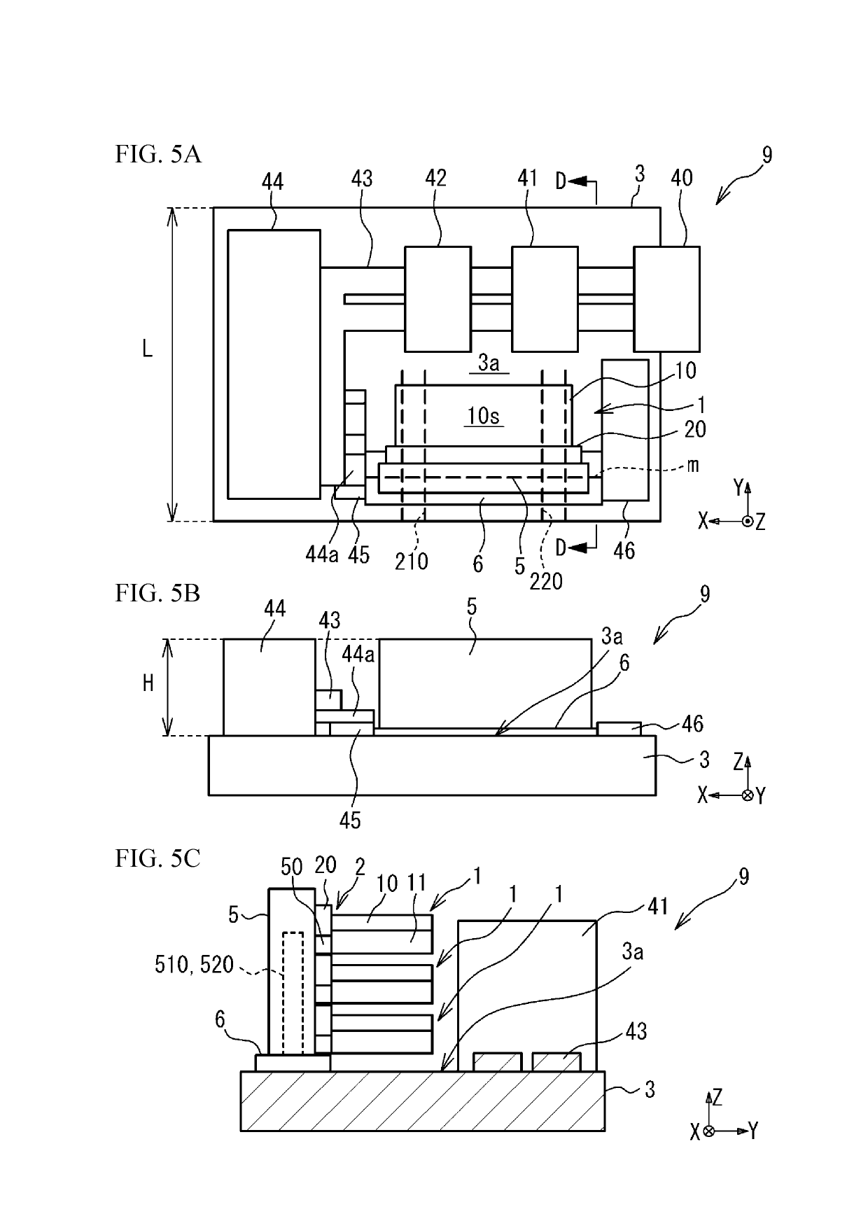

FIG. 5A is a top view illustrating another example of a PCU 9. FIG. 5B is a side view illustrating the other example of the PCU 9. FIG. 5C is a cross-sectional view taken along line D-D of FIG. 5A. In FIGS. 5A to 5C, the same reference numerals are given to the same components as those in FIGS. 4A and 4B, and the description thereof will be omitted.

The PCU 9 has an adapter 5 and a support member 6 in addition to the same configuration as the above example. The adapter 5 is connected to the three power modules 1 in the Y direction. The support member 6 supports the adapter 5 on the plate surface 3a of the base plate 3. The support member 6 is, for example, a rectangular frame, and is fixed to a predetermined position between the two terminal blocks 45 and 46 on the plate surface 3a of the base plate 3 with an adhesive or the like. The adapter 5 is a substantially rectangular plate-like member, and an end of the adapter 5 is fitted into the frame of the support member 6.

Thus, the adapter 5 is supported in a posture in which a plate surface 5a of the adapter 5 is substantially orthogonal to the plate surface 3a of the base plate 3. That is, the adapter 5 stands in a direction substantially orthogonal to the plate surface 3a of the base plate 3. The adapter 5 of the present example stands in the Z direction, but the direction in which the adapter 5 stands may not be the Z direction, and may be inclined by several degrees with respect to the Z direction. In addition, adapter flow paths 510 and 520 which extend in the Z direction along the plate surface 5a of the adapter 5 are provided inside the adapter 5. The adapter flow paths 510 and 520 are connected to the plate flow paths 220 and 210, respectively, and the cooling water circulating in the cooler 11 flows through the adapter flow paths 510 and 520.

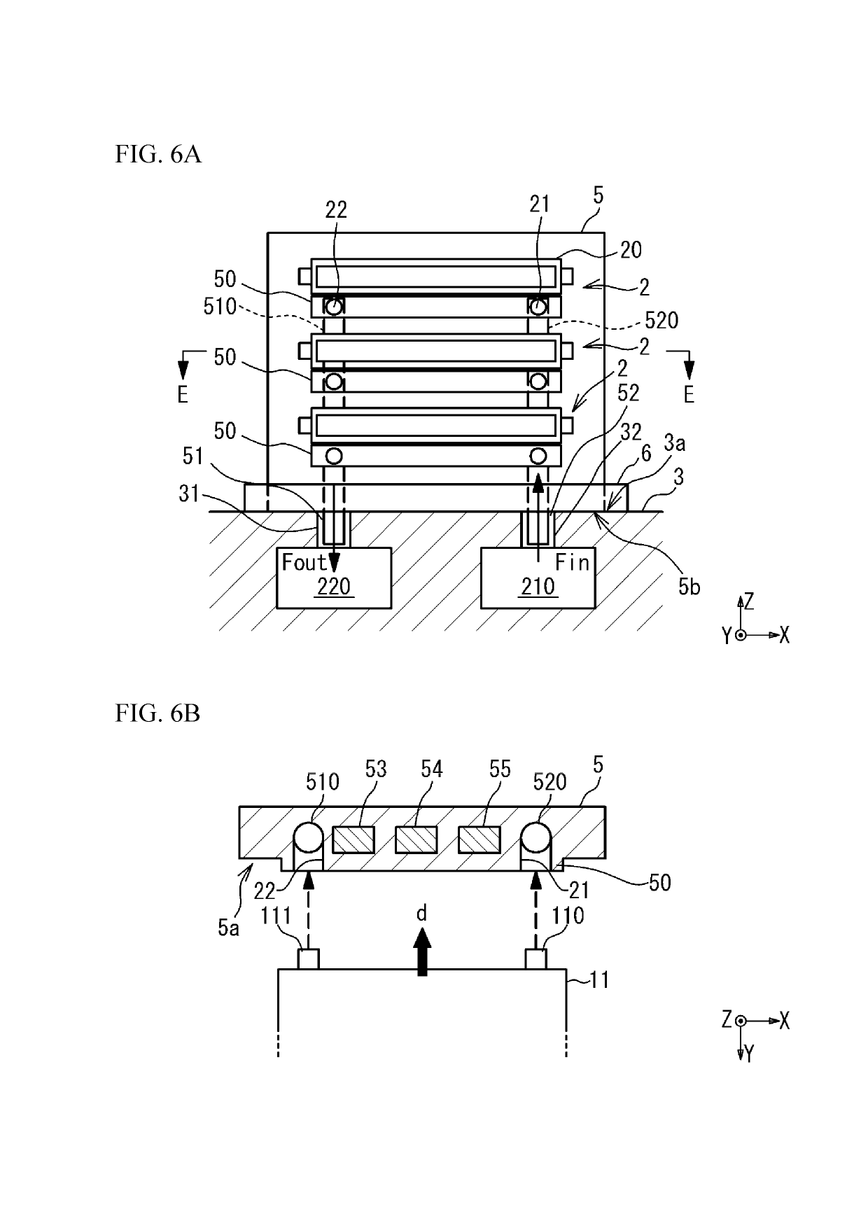

FIG. 6A is a plan view illustrating an example of the adapter 5 in a front view. FIG. 6B is a cross-sectional view taken along line E-E of FIG. 6A. FIG. 6A illustrates a cross section of the base plate 3 taken along the line m in FIG. 5A, in addition to the adapter 5. FIG. 6B illustrates an example of a state in which the cooler 11 is connected to the adapter 5. In FIGS. 6A and 6B, the same reference numerals are given to the same components as those in FIGS. 1A to 2C and FIGS. 5A to 5C, and the description thereof will be omitted.

The adapter 5 includes the three connection structures 2 arranged in the Z direction so as to correspond to the three power modules 1. The three edge connectors 20 are provided on of the adapter 5, and are arranged at substantially equal intervals in the Z direction. In addition, the connection holes 21 and 22 which respectively communicate with the adapter flow paths 510 and 520 are provided in the plate surface 5a of the adapter 5. The edge connectors 20 and the connection holes 21 and 22 are alternately arranged in the Z direction. The arrangement direction of the edge connectors 20 and the connection holes 21 and 22 may not be the Z direction, and may be inclined by about several degrees with respect to the Z direction.

The connection holes 21 and 22 are provided in a rectangular pedestal portion 50 that protrudes from the plate surface 5a of the adapter 5 to the positive Y direction. The dimension of the pedestal portion 50 is substantially equal to the distance from the side surface 11e of the cooler 11 to the end portion 10a of the circuit board 10, like the dimension of the pedestal portion 30. When the cooler 11 moves in the connecting direction d with respect to the plate surface 5a of the adapter 5, the inflow portion 110 and the outflow portion 111 are connected to the connection holes 21 and 22, respectively (see the dotted lines). Thus, the flow path 112 of the cooler 11 communicates with the adapter flow paths 510 and 520. The substantially plate shape of the adapter 5 is not a completely flat plate, but is a plate shape in which a convex portion such as the pedestal portion 30 or a concave portion (not illustrated) is formed on the plate surface 5a.

The adapter flow paths 510 and 520 extend substantially parallel along the Z direction. The connection holes 21 and 22 are formed from the adapter flow paths 510 and 520 in the Y direction, and are arranged at the same intervals as the intervals between the inflow portion 110 and the outflow portion 111 in the X direction. The three sets of the connection holes 21 and 22 are arranged at substantially equal intervals in the Z direction. The adapter flow paths 510 and 520 are connected to the plate flow paths 220 and 210 of the base plate 3 via an outlet portion 51 and an inlet portion 52 provided on a lower surface 5b of the adapter 5 in the Z direction.

The outlet portion 51 and the inlet portion 52 have a substantially cylindrical shape so that the cooling water flows therethrough, and protrude from the lower surface 5b of the adapter 5 in the negative Z direction. The base plate 3 has openings 31 and 32 that are connected to the plate flow paths 220 and 210, respectively. The openings 31 and 32 are formed in the Z direction and are connected to the outlet portion 51 and the inlet portion 52, respectively. Here, the outlet portion 51, the inlet portion 52, and the openings 31 and 32 have a sealing structure for preventing leakage of the cooling water.

The cooling water flows into the adapter flow path 520 from the plate flow path 210 through the inlet portion 52 (see reference sign Fin), and flows into the flow path 112 from the adapter flow path 520 through the connection hole 21. The cooling water flows into the adapter flow path 510 from the flow path 112 through the connection hole 22, and flows into the plate flow path 220 from the adapter flow path 510 through the outlet portion 51 (see reference sign Fout). Thus, the cooling water flows between the flow path 112 of the cooler 11 and the plate flow paths 210 and 220.

In addition, electric wires 53 to 55 insulated from each other are embedded in the adapter 5 along the Z direction. The electric wires 53 to 55 are drawn to electric terminals (not illustrated) exposed on the plate surface 5a of the adapter 5, and are electrically connected to the connector terminals 201 to 203 of the edge connector 20, respectively. The electric wires 54 and 55 are drawn from the lower surface 5b of the adapter 5 to the terminal block 45 and electrically connected to the pair of the terminals 44a of the capacitor 44. The electric wire 53 is drawn from the lower surface 5b of the adapter 5 to the terminal block 46 and electrically connected to, for example, a three phase AC motor (not illustrated).

With the above configuration, the power modules 1 are arranged in the PCU 9 such that the plate surfaces 10s of the circuit boards 10 overlap one another in a direction (Z direction) substantially orthogonal to the plate surface 3a of the base plate 3. Therefore, the space is effectively used in the Z direction. At this time, as the height of the adapter 5 holding the three power modules 1 is closer to the height H of the capacitor 44 which is a large component, a useless space is saved. In the present example, the circuit boards 10 overlap one another in the Z direction, but the direction of overlap may not be the Z direction, and may be inclined by several degrees with respect to the Z direction.

On the other hand, as described above, if the power modules 1 are arranged in the Y direction on the plate surface 3a of the base plate 3 such that the plate surfaces 10s of the circuit boards 10 are parallel to the plate surface 3a of the base plate 3, a useless space is generated above the power modules 1 in the Z direction. In the present embodiment, an example in which the three power modules 1 are mounted on the PCU 8 or 9 is described, but the number of the power modules 1 to be mounted is not limited.

As described above, the power module 1 is connected in any direction while having a capability of sufficiently cooling the IPM 100 having a large amount of heat generation. Therefore, by arranging the power modules 1 in an appropriate direction and mounting the power modules 1 on the PCU 8 or 9, the use efficiency of the space of the PCU 8 or 9 is improved.

Although some embodiments of the present disclosure have been described in detail, the present disclosure is not limited to the specific embodiments but may be varied or changed within the scope of the present disclosure as claimed.

What is claimed is:

1. A power module comprising:
a circuit board including a power semiconductor element; and
a cooler including a flow path for a cooling medium that cools the circuit board,
wherein
the cooler is integrated with the circuit board by being bonded to a surface of the circuit board,
a connection terminal capable of being connected to an edge connector is provided at an end portion of the circuit board, and
an inlet and an outlet of the flow path are opened in a connecting direction of the connection terminal with respect to the edge connector.

2. The power module according to claim 1, wherein the power semiconductor elements are embedded in the circuit board.

3. A power conversion device comprising:
the power modules each according to claim 1;
a plate member including a plate flow path communicating with the flow path of each of the power modules;
the edge connectors arranged on a plate surface of the plate member, the edge connectors being connected to the connection terminals of the circuit boards of the power modules, respectively;
the plate surface of the plate member is provided with connection holes that communicate with the plate flow path and are connected to the inlets and the outlets of the flow paths of the power modules; and
the power modules are arranged such that surfaces of the circuit boards overlap each other in a direction along the plate surface of the plate member.

4. A power conversion device comprising:
the power modules according to claim 1;
a plate member including a plate flow path communicating with the flow path of each of the power modules;
an adapter formed into a substantially plate shape, standing in a direction substantially orthogonal to a plate surface of the plate member, and including an adapter flow path connected to the plate flow path, the cooling medium flowing through the adapter flow path; and
edge connectors connected to the connection terminals of the circuit board of each of the power modules, respectively,
wherein
the adaptor is provided with sets of connection holes in a plate surface, the connection holes communicating with the adapter flow path and respectively connected to the inlets and the outlets of the flow paths of the power modules,
the edge connectors are arranged, on the plate surface of the adapter, alternately with the sets of connection holes in a direction substantially orthogonal to the plate surface of the plate member, and
the power modules are arranged such that the surfaces of the circuit boards overlap each other in the direction substantially orthogonal to the plate surface of the plate member.

5. The power conversion device according to claim 3, wherein the edge connector includes a fixing portion that fixes the power module to the edge connector.
